(19) United States
(12) Patent Application Publication
(10) Pub. No.: US 2011/0193145 A1
(43) Pub. Date: Aug. 11, 2011

(54) CRYSTAL PHASE STABILIZING STRUCTURE

(75) Inventors: Nobuyuki IKARASHI, Kanagawa (JP); Mitsuru NARIHIRO, Kanagawa (JP)

(73) Assignee: RENESAS ELECTRONICS CORPORATION, Kawasaki-shi (JP)

(21) Appl. No.: 13/022,403

(22) Filed: Feb. 7, 2011

(30) Foreign Application Priority Data
Feb. 8, 2010 (JP) 2010-025027

(51) Int. Cl. H01L 29/772; B32B 7/02

(52) U.S. Cl. 257/288; 428/212; 257/E29.242

(57) ABSTRACT

It is possible to achieve the above interface structure stabilization by forming a structure in which a fraction of Ni atoms are substituted with Pt atoms only in the first interface layer, thereby lowering the interface energy while suppressing the variation of the characteristics of NiSi and NiSi/Si interface to the minimum extent. Therefore, it is possible to contribute to the improvement of the yield ratio of elements or the improvement of reliability through the stabilization of the crystal phase of NiSi. The NiSi is formed, for example, on the surface layer of a source drain in a transistor.

The application is based on Japanese patent application No. 2010-025027, the content of which is incorporated hereinto by reference.

### BACKGROUND

1. Technical Field

The present invention relates to an interface structure in a heterogeneous material made of materials capable of having a plurality of crystal phases, which constitutes an element, and a semiconductor device.

2. Related Art

The properties of a crystalline material vary with the crystal structure or chemical composition. Therefore, in industrial products using the properties of a material capable of having a plurality of crystal structures or chemical compositions, the stability of the crystal phase has a critical effect on the characteristics or reliability of the industrial products. In addition, the variation of the crystal phase is often significantly affected by the structure of an interface in a heterogeneous material adjacent to the crystal. As a result, a technology that controls the interface structure and improves the phase stability of a crystalline material is required.

An example of a field in which there is an issue regarding the improvement of the structural stability of the interface in a heterogeneous material is that of advanced CMOS devices. NiSi is used for the joint of the advanced CMOS (refer to International Technology Roadmap for Semiconductors 2007 Edition, Front end Processes), but, in the NiSi/Si interface, NiSi₂ phases are often formed by a reaction of NiSi+Si→NiSi₂. The formation of the NiSi₂ phase shown in International Technology Roadmap for Semiconductors 2007 Edition is not desirable from the viewpoint of the application of NiSi to devices since NiSi₂ has higher resistance than NiSi, or the like.

Here, Japanese Laid-Open Patent Publication No. 2003-213407 discloses that the formation of the NiSi₂ phase is suppressed by a Ni alloy target including 0.5 to 10 at % (atomic percent) of Ti, Nb or the like as alloy elements in Ni which is to form NiSi.

In addition, Japanese Laid-Open Patent Publication No. 2005-150752 discloses that the thermal stability of an NiSi film can be obtained by forming a deposited film of a Ni alloy including alloy elements, such as Ta, added to Ni which is to form NiSi by the sputtering method.

On the other hand, a technology that suppresses the reaction of NiSi+Si→NiSi₂ by, in addition to the above, adding a large amount of Pt to NiSi and improves the stability of NiSi has been reported (refer to D. Mangelinck, J. Y. Dai, J. S. Pan, and S. K. Lahiri Appl. Phys. Lett. 75, 1736 (1999), C. Detavernier and C. Lavoie, Appl. Phys. Lett. 84. 3549 (2004), and H. Akatsu et al, MRS Proc. 1070 79 (2008)).

In D. Mangelinck, J. Y. Dai, J. S. Pan, and S. K. Lahiri Appl. Phys. Lett. 75, 1736 (1999), C. Detavernier and C. Lavoie, Appl. Phys. Lett. 84. 3549 (2004), and H. Akatsu et al, MRS Proc. 1070 79 (2008), the effect of the stability improvement by the addition of Pt is reported as typical cases in which more than or equal to 5 at % of Pt is added to Ni.

Japanese Laid-Open Patent Publication No. 2005-150752, R. W. G. Wyckoff, Crystal Structures (John Wiley & Sons, New York, London, 1963), and F. d'Heurle, J. Mat. Res. 3. 167 (1988) are examples of the above-described related art.

### SUMMARY

As described above, in D. Mangelinck, J. Y. Dai, J. S. Pan, and S. K. Lahiri Appl. Phys. Lett. 75, 1736 (1999), C. Detavernier and C. Lavoie, Appl. Phys. Lett. 84. 3549 (2004), and H. Akatsu et al, MRS Proc. 1070 79 (2008), it is reported that (i) the addition of Pt varies the orientation of NiSi, (ii) Pt tends to segregate in the boundary of NiSi. These facts suggest that structural changes in NiSi/Si interfaces caused by the addition of Pt improve the stability of crystal phases. It is described that the interfaces are stabilized since Pt increases the average interatomic distance of a NiSi layer in the case (i) and structures in which Pt segregates close to the Si side in the NiSi/Si interface are formed in the case (ii).

However, the addition of a large amount of Pt to NiSi does not only vary the properties of NiSi with the amount added, but also is not desirable from the standpoint of costs.

In order to solve the above problems, in one embodiment, there is provided a crystal phase stabilizing structure which is formed in the interface of two layers made of mutually different materials and is made of a film including the materials constituting the two layers, in which materials constituting the film have a plurality of crystal structures or chemical compositions; the film has a fraction of the atoms in a region from the interface with one of the two layers to less than or equal to ⅓ of the depth of the film substituted with atoms not included in any of the two layers in a substitution ratio of more than or equal to 10 at %; and the substitution ratio at the middle portion in the depth direction of the film is, by atom ratio, less than or equal to ⅓ of the substitution ratio in the adjacent region of the interface.

In another embodiment, there is provided a semiconductor device including a silicon layer and a metal silicide layer which is formed on at least a part of the silicon layer and includes a silicided first metal, in a region of the metal silicade layer from the interface with the silicon layer to less than or equal to ⅓ of depth of said metal silicide layer, the first metal is substituted with a second metal in a substitution ratio of more than or equal to 10 at % and the substitution ratio at the middle portion in the depth direction of the metal silicide layer is, by atom ratio, less than or equal to ⅓ of the substitution ratio in the adjacent region of the interface.

According to the present invention, it is possible to provide a crystal phase stabilizing structure and a semiconductor device capable of stabilizing crystal phases in the interface structure of a heterogeneous material made of material capable of having a plurality of crystal structures or chemical compositions.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is an electron microscope photo showing an example of the HAADF-STEM (High-angle Annular-Dark-Field-Scanning Transmission Electron Microscopy) image of an interface having the structure of the present invention.

FIG. 2A and 2B are electron microscope photos showing the other example of the HAADF-STEM image of the interface having the structure of the present invention.

FIG. 3A and 3B are photos showing the simulation results of the HAADF-STEM image of the interface having the structure of the present invention.

FIG. 4 is a cross-sectional view showing the configuration of a semiconductor device according to the example.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, the embodiments of the present invention will be described in detail with reference to the accompanying drawings.

In order to form a structure of an interface in a heterogeneous material which is to be the present invention, a Si (100) substrate is used; a hydrofluoric acid treatment is conducted on the surface of the substrate; Ni and a small amount of Pt which are necessary to form NiSi films with a desired thickness are deposited by the chemical vapor-phase reaction deposition method; and firing is conducted so as to form a NiSi film. Here, the chemical vapor-phase reaction deposition method is used to deposit Ni and Pt, but another deposition methods, such as the molecular beam epitaxy method or the like, can be used, and, in addition, it is also possible to form NiSi by supplying Si atoms together with the above atoms at the same time. Meanwhile, the amount of Pt necessary to form the structure stabilizing the interface somewhat varies with the processes for NiSi formation, such as a deposition method or the like, but it is preferable to use an amount with which a fraction of Ni atoms in the adjacent region of the interface of the NiSi film, preferably in the unit cell in the first interface atomic layer in the NiSi/Si interface are substituted by Pt atoms, and a commensurate amount is supplied.

Here, in the embodiments of the present invention, Pt is used as a substituting atom. However, it is also possible to use one kind or more than or equal to two kinds of substituting metals other than Ni, for example,

Ti, V, Cr, Mn, Co, Zr, Nb, Mo, Ru, Rh, Pd, Hf, Ta, W and Pt. In addition, the substitution ratio with respect to Ni is an amount of more than or equal to 10 at %, and a larger substituted amount further stabilizes the interface structure, which is preferable, therefore more than or equal to 13 at % is more preferable.

The substituted amount at a region closer to the middle portion of the film is set to have ⅓ of a substitution ratio at a region from the interface of the NiSi film to ⅓ of the depth of the NiSi film.

The present invention was observed by manufacturing specimens for cross-section observation (110) from the above sample through a standard method of manufacturing cross-section specimens for a Transmission Electron Microscope (TEM). The observation was conducted using a Scanning Transmission Electron Microscopy (STEM). The convergence angle of electron rays during the observation was about 20 mrad. An ADF detector was set to detect scattered electrons with an angle of 45 mrad to 100 mrad. This is called High-angle Annular-Dark-Field (HAADF) conditions.

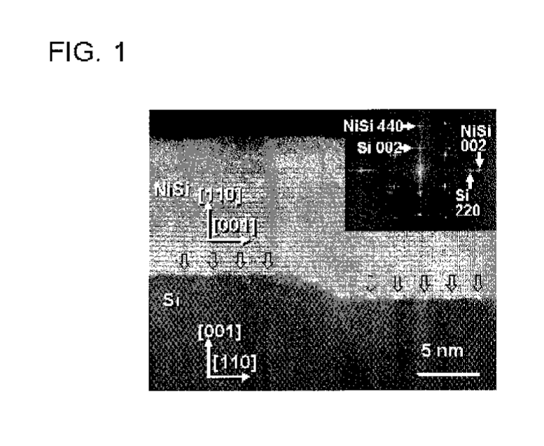

FIG. 1 shows an image of the HAADF-STEM observation of the specimens formed in the above manner. The inserted view is an image of Fourier transformation of the image of the HAADF-STEM observation.

The image of Fourier transformation suggests that the NiSi layer has a MnP structure, and the orientation relationship with the Si substrate is NiSi (110)//Si (001) and NiSi [001] // Si [110] [refer to R. W. G. Wyckoff, Crystal Structures (John Wiley & Sons, New York, London, 1963)].

The results also suggest that the incidence azimuth of the electron rays is parallel to the orientation of NiSi [110].

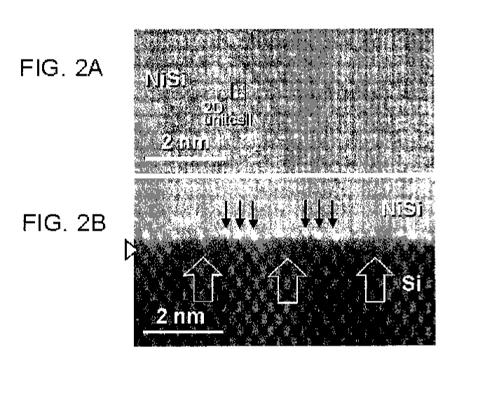

FIG. 2A and 2B are electron microscope photos of the image of HAADF-STEM observation showing the close-up of the NiSi and the interface. The box in the NiSi region shown in FIG. 2A shows a two-dimensional unit cell in the [110] projection of the crystal lattice of the NiSi. On the observation image, 4 bright points are observed in the two-dimensional unit cell. The white circles shown in the box of the two-dimensional unit cell in the drawing schematically show the bright points.

In the boundary region shown in FIG. 2B, the bright points in the boundary are indicated by black arrows. The observation results show that, in the NiSi side of the interface, the bright points are observed only in the first interface layer, and the bright points are observed on the lattice points of the STEM image pattern of the NiSi crystal, and, in addition, the bright points appear light and dark with a cycle of the two-dimensional unit cell in the 001 direction.

It is evident from the simulation results of the STEM image below that the interface has an interface structure which is to be the present invention.

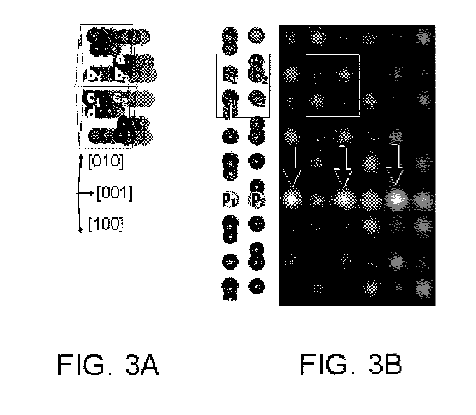

FIG. 3A is a schematic view of the atomic array in the NiSi crystal. The blue and red balls represent atoms of SiNi respectively.

FIGS. 3B is a schematic view of the atomic arrangement used for calculation and the calculation results.

The black lines in FIG. 3A indicate the unit cells of NiSi, and the boxes in FIGS. 3B indicate the two-dimensional unit cells of the [110] projection of NiSi.

The [110] projection of the atom sites a to d in FIG. 3A corresponds to the atom row of a to d in FIG. 3B.

In addition, the Ni atoms in the atom rows p1 and p2 in FIG. 3B are assumed to be substituted with Pt with a probability of ⅓.

The calculation results show that, in the [110] projection image of NiSi, the atom rows b1, b2, c1 and c2 are observed as the bright points. This is well matched with the pattern in the observation image of the observation image 2a and thus, together with the Fourier transformation image in FIG. 1, FIG. 2A shows the [110] projection image of NiSi. Furthermore, the calculation results show that the atom rows (p1 and p2) in which Pt substitutes Ni are observed to be brighter than the atom rows of NiSi b1, b2, c1 and c2. In addition, regarding the brightness of p1 and p2, although Pt substitutes Ni with the same probability, p1 is brighter than p2.

The calculation results of the NiSi crystal including the atom rows p1 and p2 in which Ni atoms are substituted with Pt atoms in FIG. 3B reproduce well the observation image of the bright points in the NiSi/Si interface in FIG. 2B, therefore it is possible to conclude that the bright points observed in the NiSi/Si interface are images of the atom rows in which the Ni atoms in NiSi have been substituted with Pt with a predetermined probability.

In addition, in the case of a high substitution probability by Pt in p1 and p2, the difference in image intensity between the atom rows a to d and p1 and p2 becomes large, that is, p1 and p2 are observed to be brighter, and in the case of a small substitution probability by Pt, it is evident that the difference in image intensity between the atom rows a to d and p1 and p2 becomes small. These result matched the result of the simulation.

In the observation results of the above FIGS. 1, 2A, and 2B, the bright points in the interface atom rows (corresponding to the atom row p1 of the model) are evidently bright compared with the atom rows a to d, but the brightness of the atom rows between the bright points (corresponding to the atom row p2 of the model) does not significantly differ from the atom rows a to d. The STEM image intensity of the Pt-substituted NiSi was reproduced to calculation images with a substitution probability by Pt of ⅓.

Therefore, the results of the above STEM observation and STEM image simulation show that, in the sample of the present invention, a structure in which Pt substitutes the Ni atoms in the first NiSi-side layer in the NiSi/Si interface in a probability of about ⅓ is formed. In addition, the strength of Ni atom sites in the second and subsequent layers is equal to the strength of the NiSi layer, and, according to the simulation, the image intensity is reproduced in a substitution by Pt of less than or equal to 10 at %. From the above results, it is possible to conclude that, in the NiSi unit cells of the second and subsequent layers, the substitution probability of Ni by Pt is less than or equal to ⅓ of the substitution probability of the unit cells in the first layer.

In addition, in the sample, the NiSi+Si→NiSi₂ reaction was not detected even after exceeding the general reaction temperature.

The above reaction temperature rise results from the fact that the lattice constant of PtSi which is 0.553 nm is larger than the lattice constant of NiSi which is 0.523 nm [refer to R. W. G. Wyckoff, Crystal Structures (John Wiley & Sons, New York, London, 1963)]. In the NiSi/Si interface, since the interatomic spacing of Si to Si (0.236 nm) is larger than the interatomic spacing of NiSi (0.230 nm), NiSi receives a tensile stress in the interface. Therefore, if Ni is substituted with Pt, the average interatomic spacing becomes large. As a result, the interface stress is relieved, thus lowering the interface energy.

On the other hand, the activation energy for nucleation ΔG* of the NiSi+Si→NiSi₂ reaction is given as ΔG*=σ² /66 G³ in which σ represents an increase of the interface energy with the reaction, and ΔG represents an increase of the Gibbs free energy with the reaction [refer to F. d'Heurle, J. Mat. Res. 3. 167 (1988)]. Therefore, the lowering of the interface energy of the interface NiSi/Si in the first phase of the reaction increases Δσ, thereby increasing ΔG*. As a result, the nucleation of NiSi₂ is suppressed.

Therefore, it is evident that the stability of the crystal phase was improved by the interface structure according to the present invention.

Such effects can be obtained not only in the case of adding Pt but also in the case of adding Pd. This results from the fact that PdSi forms the same crystal structure as that of NiSi or PtSi and also has a larger lattice constant than NiSi.

As such, in the embodiments of the present invention, it is possible to achieve the above interface structure stabilization by forming a structure in which a fraction of Ni atoms are substituted with Pt atoms only in the first interface layer, thereby lowering the interface energy while suppressing the variation of the characteristics of NiSi and NiSi/Si interface to the minimum extent. As a result, it is possible to contribute to the improvement of the yield ratio of elements or the improvement of reliability through the stabilization of the crystal phase of NiSi.

### EXAMPLE

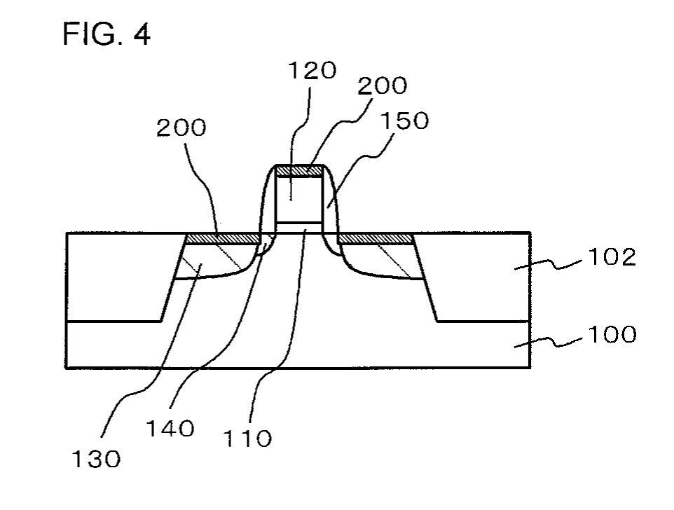

FIG. 4 is a cross-sectional view showing the configuration of a semiconductor device according to the example. The present example includes the above-described interface structure stabilizing structure in a Ni silicide layer 200. The Ni silicide layer 200 is formed on the surface layers of source drain regions 130 and at least the surface layer of a gate electrode 120 of a MOS transistor.

Specifically, a silicon layer 100 is a silicon substrate. Additionally, an element isolation layer 102 is embedded in the silicon substrate so as to separate element regions on which the MOS transistor is formed from the other regions. A gate insulating film 110 and the gate electrode 120 are formed on a part of the element regions. The gate insulating film 110 may be a silicon oxide film or may include a high-k insulating film whose dielectric constant is higher than that of silicon oxide. In the case of taking the former for the gate insulating film 110, the gate electrode 120 is a polysilicon film. In addition, in the case of taking the latter for the gate insulating film 110, the gate electrode 120 has a lamination structure including a metal gate (for example, a film of a metal nitride, such as TiN or the like) and a polysilicon film laminated in this order. Additionally, the Ni silicide layer 200 is formed on the surface layer of the gate electrode 120, and side walls 150 are formed at the side faces of the gate electrode 120.

The source drain regions 130 are formed on the silicon layer 100 located at both sides of the gate electrode 120. The source drain regions 130 are formed by introducing impurities to the silicon layer 100 and also include extension regions 140. The extension region 140 is located below the side wall 150. Additionally, the Ni silicide layer 200 is formed on the surface layer of the source drain region 130. The average thickness of the Ni silicide layer 200 located on the surface layer of the source drain region 130 is less than or equal to 20 nm, and preferably less than or equal to 10 nm.

It is apparent that the present invention is not limited to the above embodiment, and may be modified and changed without departing from the scope and spirit of the invention.

What is claimed is:

1. A crystal phase stabilizing structure which is formed in an interface of two layers made of mutually different materials and is made up of a film including said materials constituting said two layers,
wherein materials constituting said film have a plurality of crystal structures or chemical compositions;
said film has a fraction of atoms in a region from said interface with one of said two layers to less than or equal to ⅓ of depth of said film substituted with atoms not included in any of said two layers in a substitution ratio of more than or equal to 10 at %; and
said substitution ratio at a middle portion in a width direction of said film is, by atom ratio, less than or equal to ⅓ of said substitution ratio in an adjacent region of said interface.

2. The crystal phase stabilizing structure according to claim 1,
wherein said adjacent region of said interface is unit cells in a first interface layer from said interface in a film depth direction.

3. The crystal phase stabilizing structure according to claim 1,
wherein said materials constituting said interface include transition metal silicide.

4. The crystal phase stabilizing structure according to claim 1,
wherein said atoms substituted in said interface of said material constituting said interface include a transition metal.

5. The crystal phase stabilizing structure according to claim 3,
wherein said transition metal is an Ni alloy including Ni or Ni and a transition metal other than Ni.

6. The crystal phase stabilizing structure according to claim 4,
wherein said substituting atoms are at least one kind of Pt and Pd.

7. A semiconductor device, comprising:
a silicon layer; and
a metal silicide layer which is formed over at least a part of said silicon layer and includes a silicided first metal,
wherein in a region of said metal silicade layer from said interface with said silicon layer to less than or equal to ⅓ of depth of said metal silicide layer, said first metal is substituted with a second metal in a substitution ratio of more than or equal to 10 at % and
said substitution ratio at a middle portion in the depth direction of said metal silicide layer is, by atom ratio, less than or equal to ⅓ of said substitution ratio in said adjacent region of said interface.

8. The semiconductor device according to claim 7,
wherein said adjacent region of said interface is unit cells in a first layer from said interface in a film depth direction.

9. The semiconductor device according to claim 7,
wherein said metal silicide layer is formed over a surface layer of a source or a drain of a transistor.

10. The semiconductor device according to claim 7,
wherein said first metal is Ni, and said second metal includes at least one selected from Ti, V, Cr, Mn, Co, Zr, Nb, Mo, Ru, Rh, Pd, Hf, Ta, W and Pt.

11. The semiconductor device according to claim 7,
wherein said silicon layer is a surface layer of a silicon substrate.
